(19) United States
(12) Patent Application Publication
(10) Pub. No.: US 2021/0230718 A1
(43) Pub. Date: Jul. 29, 2021

(54) Cu ALLOY TARGET

(71) Applicant: ULVAC, INC., Chigasaki-shi, Kanagawa (JP)

(72) Inventor: Satoru TAKASAWA, Chigasaki-shi (JP)

(73) Assignee: ULVAC, INC., Chigasaki-shi, Kanagawa (JP)

(21) Appl. No.: 16/965,185

(22) PCT Filed: Feb. 6, 2020
(86) PCT No.: PCT/JP2020/004644

§ 371 Date: Jul. 27, 2020

(30) Foreign Application Priority Data
Apr. 19, 2019 (JP) 2019-080031

(51) Int. Cl. C22C 9/10; C22C 9/01

(52) U.S. Cl. CPC C22C 9/10; C22C 9/01

(57) ABSTRACT

There is provided a Cu alloy target including a Cap film alloy. In a case where the number of atoms of the Cap film alloy is 100 at %, when the Cap film alloy contains Cu of more than 50 at % and Al of 0.5 at % or more, the Cap film alloy contains an additive metal containing at least one metal material selected from the group consisting of Mg of 0.5 at % or more, Si of 0.5 at % or more, and Ni of 3 at % or more, or contains Ca of 0.5 at % or more as the additive metal. Adhesion between a Cap film and a Si oxide thin film formed on the Cap film by a CVD method is strong, and removal does not occur.

### TECHNICAL FIELD

This application relates to a wiring film used for a minute semiconductor device, and particularly, an electrode layer and a wiring film contacting a substrate.

### BACKGROUND

In electrical products such as a flat panel display (FPD) and a thin-film solar cell that are manufactured in recent years, it is necessary to dispose a TFT on a wide substrate. For this reason, it is necessary to form a Si oxide thin film (SiOₓ) to be a gate insulating film of the TFT and a Si oxide thin film to be a protective film of the TFT, on a large-area substrate.

In recent years, a low resistance Cu thin film is used for a wiring film on the substrate in order to cause a brightness to be uniform in the large-area FPD, and technology for improving the adhesion between the Cu thin film and the substrate and technology for improving the adhesion between the Cu thin film and a semiconductor layer are developed.

Since the Si oxide thin film used in the gate insulating film and the protective film is formed on the substrate provided with the wiring film, a CVD method that can form a film at low temperature is used. However, in order to improve performance of the TFT and characteristics of the protective film, the formation temperature of the Si oxide thin film by CVD is preferably maximized.

At the time of forming the Si oxide thin film by the CVD method, if O₂ gas or N₂O gas is added to source gas, or oxygen is released during a chemical reaction, and Cu in the wiring film is oxidized, removal occurs between the Si oxide thin film and the Cu thin film.

Further, if silane-based gas such as SiH₄ gas is used in the source gas, Si diffuses into the wiring film, and removal occurs between the Si oxide thin film and the wiring film.

For this reason, technology for preventing removal by stacking a CuNi thin film on a pure Cu thin film to form a Si oxide thin film on a surface of the CuNi thin film has been developed. However, there is still a problem in that the removal cannot be sufficiently prevented.

### CITATION LIST

### Patent Literature

Patent Literature 1: JP 2017-208533 A

### SUMMARY

### Technical Problem

Disclosed embodiments have been created to solve the disadvantages of the conventional technology, and an object thereof is to provide a wiring film having high adhesion to a Si oxide thin film, a Cu alloy target to form the wiring film, and a semiconductor element using the wiring film.

### Solution to Problem

In a first embodiment, there is provided a Cu alloy target made of a Cap film alloy, wherein, when the number of atoms of the Cap film alloy is 100 at %, the Cap film alloy contains Cu of more than 50 at %, an additive metal, and Al of 0.5 at % or more, and the additive metal contains at least one or more kinds of metal materials among three kinds of metal materials consisting of Mg of 0.5 at % or more, Si of 0.5 at % or more, and Ni of 3 at % or more.

The additive metal may include Mg of 0.5 at % or more and less than 7 at %.

The additive metal may include Si of 0.5 at % or more and less than 15 at %.

The additive metal may include Ni of 3 at % or more and less than 50 at %.

In a second embodiment, there is provided a Cu alloy target made of a Cap film alloy, wherein, when the number of atoms of the Cap film alloy is 100 at %, the Cap film alloy contains Cu of more than 50 at % and Ca of 0.5 at % or more.

### Advantageous Effects

In embodiments, since adhesion between a Cap film and a Si oxide film is high, a wiring film and the Si oxide film are not removed.

Since the Cap film used in the disclosed embodiments is a Cu alloy, the wiring film can be patterned by one etching.

### BRIEF DESCRIPTION OF DRAWINGS

FIG. 1 is a cross-sectional view illustrating a semiconductor device and a liquid crystal display device according to an embodiment.

FIGS. 2A, 2B and 2C are (first) cross-sectional views illustrating steps of manufacturing a semiconductor device and a liquid crystal display device according to an embodiment.

FIGS. 3A, 3B and 3C are (second) cross-sectional views illustrating steps of manufacturing a semiconductor device and a liquid crystal display device according to an embodiment.

FIGS. 4A and 4B are (third) cross-sectional views illustrating steps of manufacturing a semiconductor device and a liquid crystal display device according to an embodiment.

FIG. 5 is a (fourth) cross-sectional view illustrating steps of manufacturing a semiconductor device and a liquid crystal display device according to an embodiment.

FIG. 6 shows a sputtering apparatus in which a Cu alloy target according to an embodiment is used.

### BEST MODE

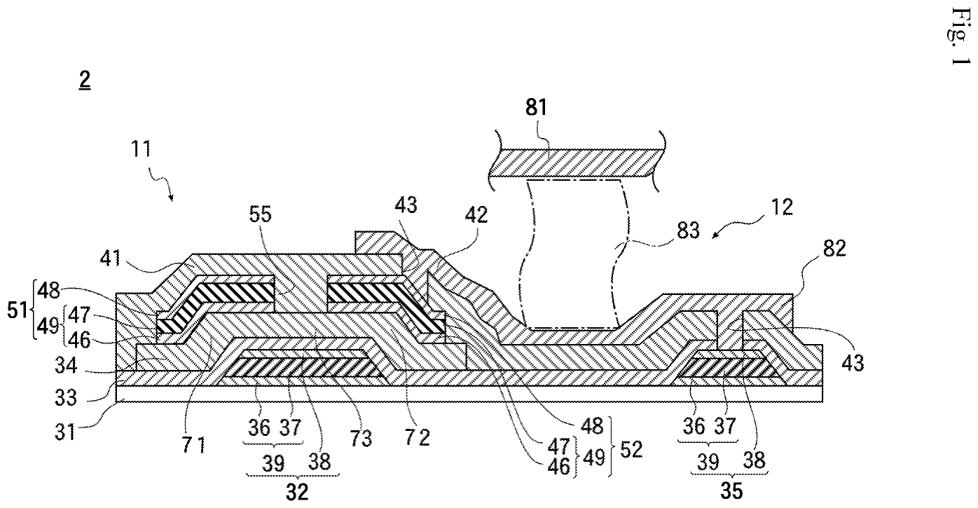

Reference numeral 2 in FIG. 1 illustrates a liquid crystal display device according to an embodiment, and a cross-sectional view of a TFT 11 according to a first example.

The TFT 11 has a gate electrode film 32. The gate electrode film 32 is elongated and disposed on a surface of a substrate 31 made of either or both of glass and resin. The substrate 31 may contain glass fiber in the resin.

A gate insulating film 33 made of Si oxide (SiOₓ) is disposed at least in a width direction, on the gate electrode film 32. A semiconductor layer 34 is disposed with a length protruding from the gate electrode film 32 on both ends in a width direction of the gate electrode film 32, on the gate insulating film 33. The gate electrode film 32 is located between one end and the other end of the semiconductor layer 34, a source electrode film 51 is disposed on one side of the semiconductor layer 34, and a drain electrode film 52 is disposed on the opposite side.

A recess 55 is provided between the source electrode film 51 and the drain electrode film 52, the source electrode film 51 and the drain electrode film 52 are electrically isolated by the recess 55, and different voltages can be applied between the source electrode film 51 and the drain electrode film 52.

A protective insulating film 41 made of Si oxide is formed on the source electrode film 51, the drain electrode film 52, and the recess 55 between the source electrode film 51 and the drain electrode film 52, and the protective insulating film 41 is used as a protective film herein.

In the case where a portion of the semiconductor layer 34 contacting the source electrode film 51 and its surrounding portion are defined as a source region 71, a portion of the semiconductor layer 34 contacting the drain electrode film 52 and its surrounding portion are defined as a drain region 72, and a region between the source region 71 and the drain region 72 is defined as a channel region 73, when a channel layer is formed in the channel region 73 by applying a gate voltage to the gate electrode film 32 in a state where a voltage is applied between the source electrode film 51 and the drain electrode film 52, the source region 71 and the drain region 72 are connected by the channel layer with low resistance, and as a result, the source electrode film 51 and the drain electrode film 52 are electrically connected, and the TFT 11 becomes conductive.

Here, a polarity of a semiconductor of the channel region 73 is the same as a polarity of a semiconductor of the source region 71 and a polarity of a semiconductor of the drain region 72, and a polarity of the channel layer is the same as the polarity of the semiconductor of the channel region 73.

However, cases where the polarity of the semiconductor of the channel region 73 is different from the polarity of the semiconductor of the source region 71 and the polarity of the semiconductor of the drain region 72, and the polarity of the channel layer is the same as the polarity of the semiconductor of the source region 71 and the polarity of the semiconductor of the drain region 72 are also included in disclosed embodiments.

If the application of the gate voltage is stopped, the channel layer disappears, and the source electrode film 51 and the drain electrode film 52 have high resistance therebetween and are electrically isolated.

A pixel electrode 82 is disposed in the liquid crystal display unit 12, and a liquid crystal 83 is disposed on the pixel electrode 82. An upper electrode 81 is located on the liquid crystal 83, and when a voltage is applied between the pixel electrode 82 and the upper electrode 81, polarization characteristic of light passing through the liquid crystal 83 is changed, and light transmittance of a polarization filter (not shown) is controlled.

The pixel electrode 82 is electrically connected to the source electrode film 51 or the drain electrode film 52 (here, the drain electrode film 52), and the TFT 11 is turned on or off to start or stop the voltage application to the pixel electrode 82.

Here, the pixel electrode 82 is made of a part of a transparent conductive layer 42 connected to the drain electrode film 52. The transparent conductive layer 42 is made of, for example, ITO.

A wiring film 35 is disposed under the transparent conductive layer 42.

Each of the wiring film 35 and the gate electrode film 32 has a low-resistance body film 39 and a Cap film 38 disposed on the body film 39 and having higher resistivity than the body film 39. Further, each of the source electrode film 51 and the drain electrode film 52 has a low-resistance body film 49 and a Cap film 48 disposed on the body film 49 and having higher resistivity than the body film 49.

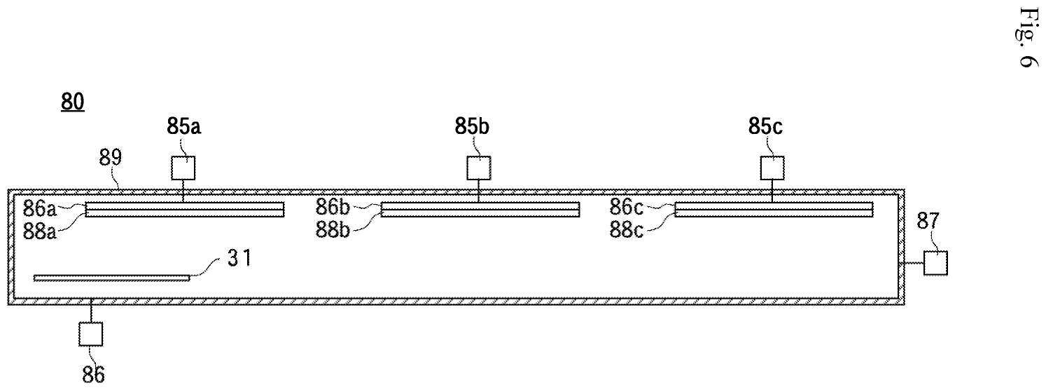

Steps of manufacturing the TFT 11 will now be described. Referring to FIG. 6, reference numeral 80 indicates a sputtering apparatus, and it is considered that the gate electrode film 32 and the wiring film 35, and the source electrode film 51 and the drain electrode film 52 are formed by the sputtering apparatus 80.

The sputtering apparatus 80 has a vacuum chamber 89. In the vacuum chamber 89, first to third cathode electrodes 86a to 86c are disposed. A first target 88a made of an adhering layer alloy is disposed in the first cathode electrode 86a, a second target 88b made of pure copper is disposed in the second cathode electrode 86b, and a Cu alloy target 88c made of a Cap film alloy is disposed in the third cathode electrode 86c.

The Cu alloy target 88c is a Cu alloy target made of a Cap film alloy, and two kinds of Cu alloy targets are prepared: a Cu alloy target obtained by forming a Cap film alloy containing aluminum atoms (Al) and a Cu alloy target obtained by forming a Cap film alloy containing calcium atoms (Ca).

When the number of atoms of the Cap film alloy is 100 at %, the Cap film alloy containing Al contains copper atoms (Cu) of more than 50 at %, an additive metal, and Al of 0.5 at % or more, and the additive metal contains at least one or more kinds of metal materials among three kinds of metal materials consisting of magnesium atoms (Mg) of 0.5 at % or more, silicon atoms (Si) of 0.5 at % or more, and nickel atoms (Ni) of 3 at % or more.

When the number of atoms of the Cap film alloy is 100 at %, the Cap film alloy containing Ca is a Cu alloy target containing Cu of more than 50 at % and Ca of 0.5 at % or more.

In this example, a Cu alloy target obtained by forming any one of the two kinds of Cap film alloys is disposed in the vacuum chamber 89 of the sputtering apparatus 80 as the Cu alloy target 88c.

The vacuum chamber 89 is evacuated by a vacuum exhaust device 86. At the time of sputtering, sputtering gas made of rare gas such as Ar gas is introduced from a gas source 87 into the vacuum chamber 89, and a sputtering voltage is applied to the first to third cathode electrodes 86a to 86c by first to third sputtering power supplies 85a to 85c to start sputtering of the first target 88a, the second target 88b, and the Cu alloy target 88c.

The substrate 31 is carried into the vacuum chamber 89, the substrate 31 as an object to be film-formed is carried into the vacuum chamber 89 of the sputtering apparatus 80, the carried substrate 31 is faced to the first and second targets 88a and 88b in this order, an adhering layer is formed by sputtering the first target 88a, a low-resistance layer is formed on the adhering layer by sputtering the second target 88b, and the body film to be a low-resistance layer of a two-layer structure including the adhering layer and the low-resistance layer is formed on the substrate 31.

Next, the Cap film is formed on the body film by sputtering the Cu alloy target 88c on the substrate 31 provided with the body film. The Cap film contacts the low-resistance layer.

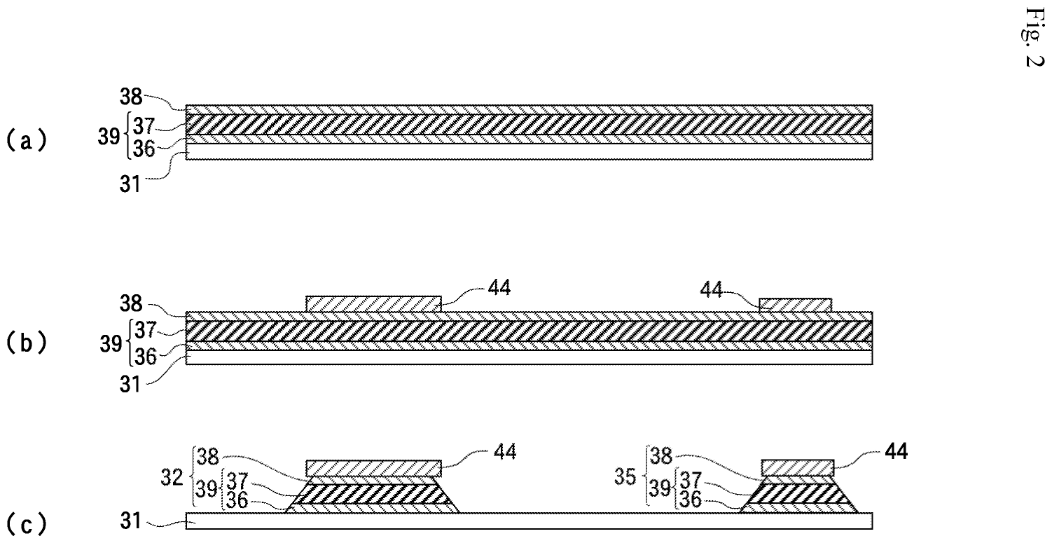

Reference numeral 36 in FIG. 2A indicates the adhering layer, reference numeral 37 indicates the low-resistance layer, and reference numeral 39 indicates the body film. Reference numeral 38 indicates the Cap film.

When the thin films 36 to 38 are formed, oxygen gas or gas having oxygen atoms in a chemical structure is not introduced into the vacuum chamber 89, and oxygen is not contained in the thin films 36 to 38.

Next, as shown in FIG. 2B, patterned resist films 44 are formed on the Cap film 38. If the substrate 31 provided with the body film 39 and the Cap film 38 is immersed in an etching solution for etching Cu, the Cap film 38 in a portion exposed between the resist film 44 and the resist film 44 is etched with the same etching solution. Next, the body film 39 in a portion exposed by the etching of the Cap film 38 is etched by the same etching solution as the etching solution that has etched the Cap film 38.

FIG. 2C shows the above state, in which the body film 39 and the Cap film 38 are partially removed, and the gate electrode film 32 and the wiring film 35 are formed on the substrate 31 by the remaining portion.

The surface of the substrate 31 is exposed except for the portions where the gate electrode film 32 and the wiring film 35 are located. After removing the resist film 44, the substrate 31 is carried into a CVD device, a temperature of the substrate 31 is increased to a temperature of 200° C. or more and 350° C. or less, silane gas is introduced into the CVD device as source gas, oxygen gas is introduced as reaction gas, argon gas is introduced as dilution gas, and the source gas and reaction gas are chemically reacted (CVD method).

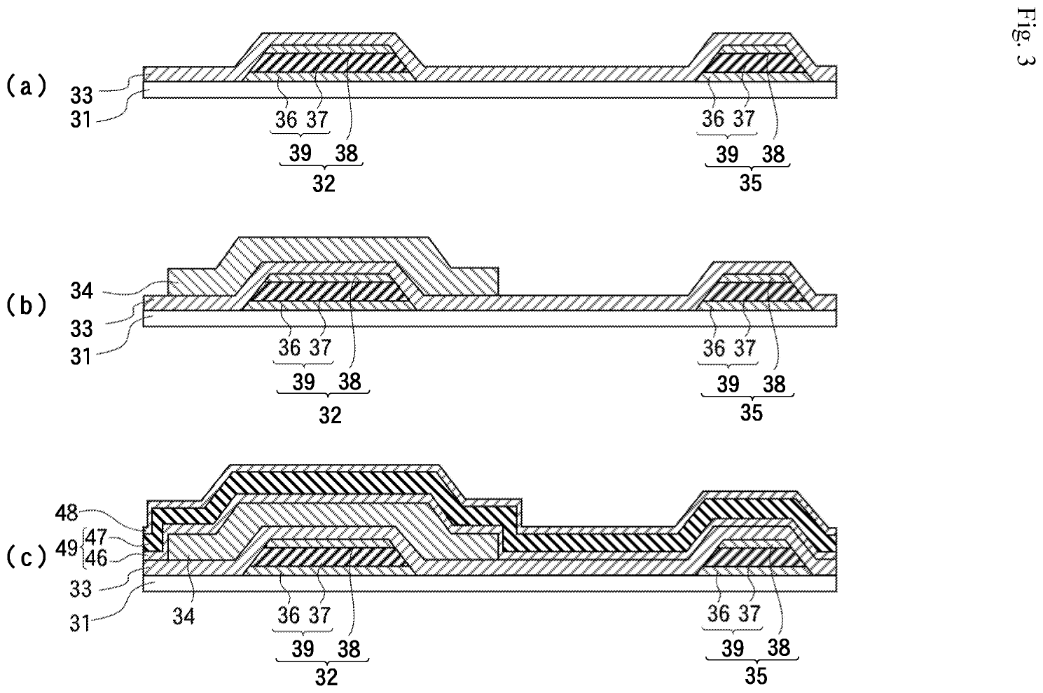

If Si oxide is generated by the chemical reaction, as shown in FIG. 3A, the Si oxide is deposited on the surface of the substrate 31, the surface of the gate electrode film 32, and the surface of the wiring film 35, and the gate insulating film 33 made of a Si oxide thin film is formed.

Next, the substrate 31 is moved to another film forming device, a thin film made of a semiconductor material (for example, a Si semiconductor or an oxide semiconductor) is formed on the gate insulating film 33 and patterned, and the semiconductor layer 34 shown in FIG. 3B is formed on the gate insulating film 33.

The substrate 31 provided with the semiconductor layer 34 is carried into the vacuum chamber 89 of the sputtering apparatus 80, and the first target 88a, the second target 88b, and the Cu alloy target 88c are sputtered. As shown in FIG. 3C, the adhering layer 46 is formed on the semiconductor layer 34, the low-resistance layer 47 is formed on the adhering layer 46, the body film 49 including the adhering layer 46 and the low-resistance layer 47 is obtained, and the Cap film 48 is formed on the body film 49. The Cap film 48 contacts the low-resistance layer 47.

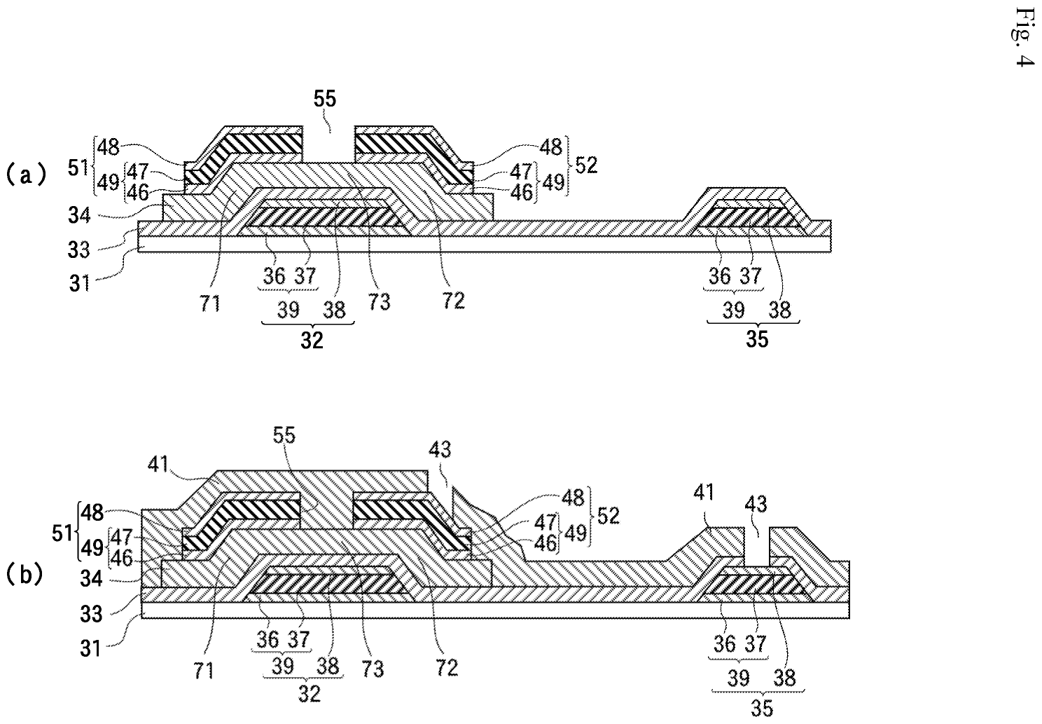

Next, a metal layer including the body film 49 and the Cap film 48 is patterned to form the source electrode film 51 and the drain electrode film 52, as shown in FIG. 4A. Each of the source electrode film 51 and the drain electrode film 52 has the body film 49 and the Cap film 48, the source electrode film 51 contacts the source region 71, and the drain electrode film 52 contacts the drain region 72.

The source electrode film 51 and the drain electrode film 52 are located on one side of the semiconductor layer 34 in the width direction and on the opposite side thereof, and the gate electrode film 32 and the gate insulating film 33 contacting the gate electrode film 32 are located between them.

The substrate 31 in this state is carried into the CVD device, the temperature of the substrate 31 is increased to a temperature of 250° C. or more and 350° C. or less, silane gas is introduced as the source gas, oxygen gas is introduced as reaction gas, and argon gas is introduced as dilution gas inside the CVD device, Si oxide is deposited by the CVD method and patterned, and the protective insulating film 41 made of Si oxide is obtained as shown in FIG. 4B.

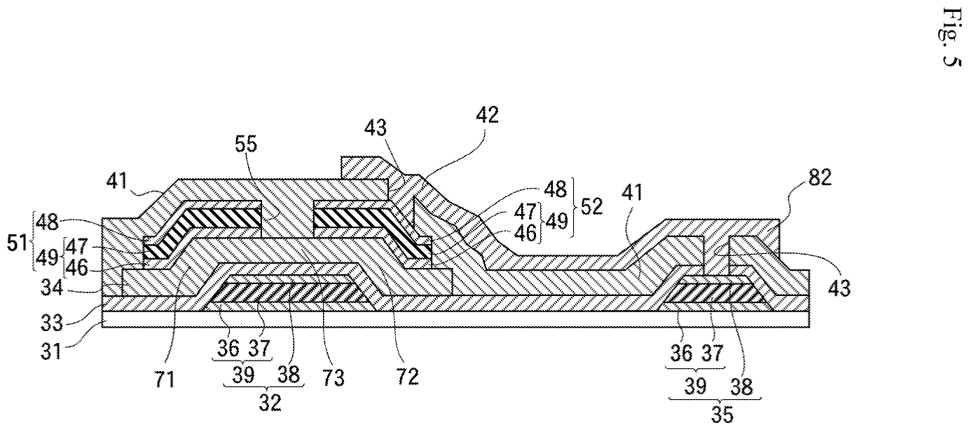

A connection hole 43 used as a via hole, a contact hole, or the like is formed in the protective insulating film 41 by patterning. The surfaces of the Cap films 38 and 48 included in the drain electrode film 52, the source electrode film 51, or the wiring film 35 are exposed to a bottom surface of the connection hole 43, and in that state, a patterned transparent conductive layer is formed on the protective insulating film 41. Reference numeral 42 in FIG. 5 indicates the patterned transparent conductive layer, and reference numeral 82 indicates a pixel electrode formed by the transparent conductive layer 42.

Then, when the liquid crystal 83 and the upper electrode 81 are disposed on the pixel electrode 82 in a subsequent step, the liquid crystal display device 2 shown in FIG. 1 is obtained.

As described above, in the TFT 11, the gate insulating film 33 made of Si oxide is formed on the surface of the gate electrode film 32 and the surface of the wiring film 35 by the CVD method, and the protective insulating film 41 made of Si oxide is formed on the surface of the drain electrode film 52 and the surface of the source electrode film 51 by the CVD method. Since the protective insulating film 41 and the gate insulating film 33 contact the Cap films 38 and 48 and oxidation of Cu in the Cap films 38 and 48 and diffusion of Si into the Cap films 38 and 48 are prevented, removal between the gate insulating film 33 and the gate electrode film 32 and the wiring film 35 and removal between the protective insulating film 41 and the source electrode film 51 and the drain electrode film 52 are prevented.

### EXAMPLES

<Removal Test>

A plurality of Cu alloy targets made of Cap film alloys having different compositions are manufactured and are sequentially disposed in the sputtering apparatus 80 as Cu alloy targets.

First, first and second targets made of Cu alloys or pure Cu are sputtered to form a body film including an adhering layer and a low-resistance layer on a surface of a glass substrate. Next, the Cu alloy target disposed in the sputtering apparatus 80 is sputtered to form a Cap film on the body film, and a wiring film including the body film and the Cap film is obtained.

The temperature of the glass substrate provided with the wiring film is increased, and source gas, oxygen gas, and dilution gas are introduced to cause a chemical reaction, and an insulating film made of Si oxide is formed on the Cap film with being in contact with the Cap film.

A two-layer film including the wiring film and the insulating film on the glass substrate is cut into squares of 1 cm×1 cm to form 100 square masses made of small pieces of the two-layer film, adhesive tape is pasted on each mass, and the adhesive tape is removed from the two-layer film.

At this time, the number of masses removed between the wiring film and the insulating film is counted for each composition of the Cap film alloy.

A case where the number of removed masses is 0/100 is determined as a good product (◯), a case where the number of removed masses is 1/100 or more and 10/100 or less is determined as a normal product (Δ), a case where the number of removed masses is 11/100 or more and 49/100 or less is determined as an unusable product (×), and a case where the number of removed masses is 50/100 or more is determined as a defective product (××).

The removal test results are shown in the following Tables 1 to 4.

<Cu—Al—Mg>

A Cu alloy target is manufactured by producing a Cap film alloy containing Al in a range of 0 at % or more and 25 at % or less and containing Mg, which is the metal material, in a range of 0.5 at % or more and 7 at % or less as the additive metal when the number of atoms of the Cap film alloy is 100 at %, the Cap film is formed on the body film by sputtering, an insulating film is formed on the Cap film by a CVD method in a temperature range of 200° C. or more and 350° C. or less, and the removal test is performed.

The film forming conditions including the content of Al, the content of Mg, and the CVD temperature, and the removal test results corresponding to the film forming conditions are described in the following Table 1.

TABLE 1
Cu—Al—Mg

| | |
|---|---|
| Added metals | CVD temperature |
| (at %) | (° C.) |

| Al | Mg | 200 | 250 | 300 | 350 |
|---|---|---|---|---|---|
| 0 | 8.5 | X | X | XX | XX |
| | 3 | X | X | X | X |
| | 5 | X | X | X | X |
| | 7 | X | X | X | X |
| 0.5 | 0.5 | ◯ | ◯ | ◯ | ◯ |
| | 3 | ◯ | ◯ | ◯ | ◯ |
| | 5 | ◯ | ◯ | ◯ | ◯ |

| | |
|---|---|
| 7 | Target cannot be manufactured |

| | | | | | |
|---|---|---|---|---|---|
| 5 | 3 | ◯ | ◯ | ◯ | ◯ |
| | 5 | ◯ | ◯ | ◯ | ◯ |
| 20 | 0.5 | ◯ | ◯ | ◯ | ◯ |
| | 3 | ◯ | ◯ | ◯ | ◯ |
| | 5 | ◯ | ◯ | ◯ | ◯ |

| | | |
|---|---|---|
| | 7 | Target cannot be manufactured |
| 25 | 3 | Target cannot be manufactured |
| | 5 | Target cannot be manufactured |

From Table 1, the Cap film preferably contains Al of 0.5 at % or more and Mg of 0.5 at % or more, because all products become good products.

When Al of 25 at % or more is contained or when Mg of 7 at % or more is contained, the Cu alloy target cannot be produced by current technology. Therefore, Mg may be contained in a range of less than 7 at %. However, because there is a possibility that the Cu alloy target can be formed even when Mg of 7 at % or more is contained, the content of Mg is not limited to less than 7 at %.

<Cu—Al—Si>

Next, a Cu alloy target is manufactured by producing a Cap film alloy containing Al in a range of 0 at % or more and 25 at % or less and containing Si ,which is the metal material, in a range of 0.5 at % or more and 15 at % or less as the additive metal when the number of atoms of the Cap film alloy is 100 at %, the Cap film is formed on the body film by sputtering, the insulating film is formed on the Cap film by the CVD method in a temperature range of 200° C. or more and 350° C. or less, and the removal test is performed.

The film forming conditions including the content of Al, the content of Si, and the CVD temperature, and the removal test results corresponding to the film forming conditions are described in the following Table 2.

TABLE 2
Cu—Al—Si

| | |
|---|---|
| Added metals | CVD temperature |
| (at %) | (° C.) |

| Al | Si | 200 | 250 | 300 | 350 |
|---|---|---|---|---|---|
| 0 | 0.5 | X | X | XX | XX |
| | 5 | X | X | X | X |
| | 10 | X | X | X | X |
| | 15 | X | X | X | X |
| 0.5 | 0.5 | ◯ | ◯ | ◯ | ◯ |
| | 5 | ◯ | ◯ | ◯ | ◯ |
| | 10 | ◯ | ◯ | ◯ | ◯ |

| | |
|---|---|
| 15 | Target cannot be manufactured |

| | | | | | |
|---|---|---|---|---|---|
| 5 | 5 | ◯ | ◯ | ◯ | ◯ |
| | 10 | ◯ | ◯ | ◯ | ◯ |
| 20 | 0.5 | ◯ | ◯ | ◯ | ◯ |
| | 5 | ◯ | ◯ | ◯ | ◯ |
| | 10 | ◯ | ◯ | ◯ | ◯ |

| | | |
|---|---|---|
| | 15 | Target cannot be manufactured |
| 25 | 5 | Target cannot be manufactured |
| | 10 | Target cannot be manufactured |

From Table 2, Al of 0.5 at % or more and Si of 0.5 at % or more are preferably contained, because all products become good products.

When Al of 25 at % or more is contained or when Si of 15 at % or more is contained, the Cu alloy target cannot be produced by the current technology. Therefore, Si may be contained in a range of less than 15 at %. However, because there is a possibility that the Cu alloy target can be formed even when Si of 15 at % or more is contained, the content of Si is not limited to the range of less than 15 at %.

<Cu—Al—Ni>

A Cu alloy target is manufactured by producing a Cap film alloy containing Al in a range of 0 at % or more and 25 at % or less and containing Ni,which is the metal material, in a range of 3 at % or more and 50 at % or less as the additive metal when the number of atoms of the Cap film alloy is 100 at %, the Cap film is formed on the body film by sputtering, the insulating film is formed on the Cap film by the CVD method in a temperature range of 200° C. or more and 350° C. or less, and the removal test is performed.

The film forming conditions including the content of Al, the content of Ni, and the CVD temperature, and the removal test results corresponding to the film forming conditions are described in the following Table 3.

TABLE 3
Cu—Al—Ni

| | |
|---|---|
| Added metals | CVD temperature |
| (at %) | (° C.) |

| Al | Ni | 200 | 250 | 300 | 350 |
|---|---|---|---|---|---|
| 0 | 3 | X | X | XX | XX |
| | 15 | X | X | X | X |
| | 30 | X | X | X | X |
| | 50 | X | X | X | X |
| 0.5 | 3 | ◯ | ◯ | ◯ | ◯ |
| | 15 | ◯ | ◯ | ◯ | ◯ |
| | 30 | ◯ | ◯ | ◯ | ◯ |

| | |
|---|---|
| 50 | Target cannot be manufactured |

| | | | | | |
|---|---|---|---|---|---|
| 5 | 15 | ◯ | ◯ | ◯ | ◯ |
| | 30 | ◯ | ◯ | ◯ | ◯ |
| 20 | 3 | ◯ | ◯ | ◯ | ◯ |
| | 15 | ◯ | ◯ | ◯ | ◯ |
| | 30 | ◯ | ◯ | ◯ | ◯ |

| | | |
|---|---|---|
| | 50 | Target cannot be manufactured |
| 25 | 15 | Target cannot be manufactured |
| | 30 | Target cannot be manufactured |

From Table 3, Al of 0.5 at % or more and Ni of 3 at % or more are preferably contained, because all products become good products.

When Al of 25 at % or more is contained or when Ni of 50 at % or more is contained, the Cu alloy target cannot be produced by the current technology. Therefore, Ni may be contained in a range of less than 50 at %.

<Cu—Ca>

A Cu alloy target is manufactured by producing a Cap film alloy containing Ca,which is the metal material, in a range of 0 at % or more and 10 at % or less as the additive metal when the number of atoms of the Cap film alloy is 100 at %, the Cap film is formed on the body film by sputtering, the insulating film is formed on the Cap film by the CVD method in a temperature range of 200° C. or more and 350° C. or less, and the removal test is performed.

The film forming conditions including the content of Cu and the CVD temperature, and the removal test results corresponding to the film forming conditions are described in the following Table 4.

TABLE 4
Cu—Ca

| | |
|---|---|
| Added metals | CVD temperature |
| (at %) | (° C.) |

| Ca | — | 200 | 250 | 300 | 350 |
|---|---|---|---|---|---|
| 0 | — | X | X | XX | XX |
| 0.5 | — | ◯ | ◯ | ◯ | ◯ |
| 1 | — | ◯ | ◯ | ◯ | ◯ |
| 3 | — | ◯ | ◯ | ◯ | ◯ |
| 5 | — | ◯ | ◯ | ◯ | ◯ |

| | | |
|---|---|---|
| 7 | — | Target cannot be manufactured |
| 10 | — | Target cannot be manufactured |

From Table 4, Ca of 0.5 at % or more is preferably contained, because all products become good products.

When Ca of 7 at % or more is contained, the Cu alloy target cannot be produced by the current technology. Therefore, Ca may be contained in a range of less than 7 at %. However, because there is a possibility that the Cu alloy target can be formed even when Ca of 7 at % or more is contained, the content of Ca is not limited to the range of less than 7 at %.

<Cu—Al>

As a comparative example, a Cu alloy target is manufactured by producing a Cap film alloy containing Al in a range of 0 at % or more and 25 at % or less when the number of atoms of the Cap film alloy is 100 at %, the Cap film is formed on the body film by sputtering, the insulating film is formed on the Cap film by the CVD method in a temperature range of 200° C. or more and 350° C. or less, and the removal test is performed.

The film forming conditions including the content of Al and the CVD temperature, and the removal test results corresponding to the film forming conditions are described in the following Table 5.

TABLE 5
Cu—Al

| | |
|---|---|
| Added metals | CVD temperature |
| (at %) | (° C.) |

| Al | — | 200 | 250 | 300 | 350 |
|---|---|---|---|---|---|
| 0 | — | X | X | XX | XX |
| 0.5 | — | Δ | Δ | Δ | Δ |
| 1 | — | Δ | Δ | Δ | Δ |
| 5 | — | Δ | Δ | Δ | Δ |
| 10 | — | Δ | Δ | Δ | Δ |
| 20 | — | Δ | Δ | Δ | Δ |

| | | |
|---|---|---|
| 25 | — | Target cannot be manufactured |

When Al of 0.5 at % or more is contained, unusable products and defective products are not generated, and a wiring film and an insulating film that can withstand actual use are obtained. However, products are just normal products, and good products are not obtained. Therefore, it can be seen that a preferable range cannot be obtained when only Al is added.

When Al of 25 at % or more is added, the Cu alloy target cannot be produced by the current technology.

<Conclusion>

As described above, when the number of atoms of the Cap film alloy is 100 at %, the Cu alloy target made of the Cap film alloy contains Cu of more than 50 at %, the additive metal, and Al of 0.5 at % or more. The additive metal may contain at least one or more kinds of metal materials among three kinds of metal materials consisting of Mg of 0.5 at % or more, Si of 0.5 at % or more, and Ni of 3 at % or more.

Further, in the Cu alloy target made of the Cap film alloy, when the number of atoms of the Cap film alloy is 100 at %, the Cap film alloy may contain Cu of more than 50 at % and Ca of 0.5 at % or more.

The composition of the Cap film obtained by sputtering the Cu alloy target is the same as the composition of the Cu alloy target. In the semiconductor element, the wiring film having the above composition can be used for the gate electrode film, the source electrode film, or the drain electrode film and the wiring film connecting these electrode films.

In view of the above, in a first embodiment, a wiring film having a Cap film made of a Cap film alloy and having a body film with lower resistivity than the Cap film can be obtained, wherein the Cap film and the body film are made into a stacked layer structure, wherein when the number of atoms of the Cap film alloy is 100 at %, the Cap film alloy contains Cu of more than 50 at %, an additive metal, and Al of 0.5 at % or more, wherein the additive metal contains at least one or more kinds of metal materials among three kinds of metal materials consisting of Mg of 0.5 at % or more, Si of 0.5 at % or more, and Ni. of 3 at % or more, and wherein the Cap film contacts an insulating film containing Si oxide.

In a second embodiment, a wiring film having a Cap film made of a Cap film alloy and having a body film with lower resistivity than the Cap film can be obtained, wherein the Cap film and the body film are made into a stacked layer structure, wherein when the number of atoms of the Cap film alloy is 100 at %, the Cap film alloy contains Cu of more than 50 at % and Ca of 0.5 at % or more.

In a third embodiment, a semiconductor device including a semiconductor layer, a gate insulating film disposed to contact the semiconductor layer and a gate electrode film facing the semiconductor layer with the gate insulating film interposed therebetween can be obtained, wherein in the semiconductor layer, a channel region is provided at a portion facing the gate electrode film, a source region and a drain region are provided on both sides of the channel region, and the source electrode film and the drain electrode film contact the source region and the drain region respectively, wherein the gate electrode film has a Cap film made of a Cap film alloy and has a body film with lower resistivity than the Cap film, wherein the Cap film and the body film are made into a stacked layer structure, wherein when the number of atoms of the Cap film alloy is 100 at %, the Cap film alloy contains Cu of more than 50 at %, an additive metal, and Al of 0.5 at % or more, wherein the additive metal contains at least one or more kinds of metal materials among three kinds of metal materials consisting of Mg of 0.5 at % or more, Si of 0.5 at % or more, and Ni of 3 at % or more, wherein the gate insulating film contains Si oxide, and wherein the Cap film contacts the gate insulating film.

In a fourth embodiment, a semiconductor device including a semiconductor layer, a gate insulating film disposed to contact the semiconductor layer and a gate electrode film facing the semiconductor layer with the gate insulating film interposed therebetween can be obtained, wherein in the semiconductor layer, a channel region is provided at a portion facing the gate electrode film, a source region and a drain region are provided on both sides of the channel region, and the source electrode film and the drain electrode film contact the source region and the drain region, wherein the gate electrode film has a Cap film made of a Cap film alloy and has a body film with lower resistivity than the Cap film, wherein the Cap film and the body film are made into a stacked layer structure, wherein when the number of atoms of the Cap film alloy is 100 at %, the Cap film alloy contains Cu of more than 50 at % and Ca of 0.5 at % or more, wherein the gate insulating film contains Si oxide, and wherein the Cap film contacts the gate insulating film.

In a fifth embodiment, a semiconductor device including a semiconductor layer, a gate insulating film disposed to contact the semiconductor layer and a gate electrode film facing the semiconductor layer with the gate insulating film interposed therebetween can be obtained, wherein in the semiconductor layer, a channel region is provided at a portion facing the gate electrode film, a source region and a drain region are provided on both sides of the channel region, wherein one surface of a source electrode film and one surface of a drain electrode film contact the source region and the drain region respectively, wherein an opposite surface of the source electrode film and an opposite surface of the drain electrode film contact the insulating film, wherein one or both of the electrode films of the source electrode film and the drain electrode film have a Cap film made of Cap film alloy and have a body film with lower resistivity than the Cap film, wherein the Cap film and the body film are made into a stacked layer structure, wherein when the number of atoms of the Cap film alloy is 100 at %, the Cap film alloy contains Cu of more than 50 at %, an additive metal, and Al of 0.5 at % or more, wherein the additive metal contains at least one or more kinds of metal materials among three kinds of metal materials consisting of Mg of 0.5 at % or more, Si of 0.5 at % or more, and Ni of 3 at % or more, and wherein the insulating film contains Si oxide, and wherein the Cap film contacts the insulating film.

In a sixth embodiment, a semiconductor device including a semiconductor layer, a gate insulating film disposed to contact the semiconductor layer and a gate electrode film facing the semiconductor layer with the gate insulating film interposed therebetween can be obtained, wherein in the semiconductor layer, a channel region is provided at a portion facing the gate electrode film, a source region and a drain region are provided on both sides of the channel region, wherein one surface of a source electrode film and one surface of a drain electrode film contact the source region and the drain region respectively, wherein an opposite surface of the source electrode film and an opposite surface of the drain electrode film contact the insulating film, wherein one or both of the electrode films of the source electrode film and the drain electrode film have a Cap film made of Cap film alloy and have a body film with lower resistivity than the Cap film, wherein the Cap film and the body film are made into a stacked layer structure, wherein when the number of atoms of the Cap film alloy is 100 at %, the Cap film alloy contains Cu of more than 50 at % and Ca of 0.5 at % or more, wherein the insulating film contains Si oxide, and wherein the Cap film contacts the insulating film.

In a seventh embodiment, a liquid crystal display device including a substrate, a wiring film provided on a front surface of the substrate, a pixel electrode layer arranged on the substrate, a liquid crystal arranged on the pixel electrode layer and an upper electrode layer arranged on the liquid crystal can be obtained, wherein the pixel electrode layer is electronically connected to the wiling film, wherein the wiring film has a Cap film made of a Cap film alloy and has a body film with lower resistivity than the Cap film, wherein when the number of atoms of the Cap film alloy is 100 at %, the Cap film alloy contains Cu of more than 50 at %, an additive metal, and Al of 0.5 at % or more, wherein the additive metal contains at least one or more kinds of metal materials among three kinds of metal materials consisting of Mg of 0.5 at % or more, Si of 0.5 at % or more, and Ni of 3 at % or more, and wherein the Cap film contacts an insulating film containing Si oxide.

In an eighth embodiment, a liquid crystal display device including a substrate, a wiring film provided on a front surface of the substrate, a pixel electrode layer arranged on the substrate, a liquid crystal arranged on the pixel electrode layer and an upper electrode layer arranged on the liquid crystal can be obtained, wherein the pixel electrode layer is electronically connected to the wiling film, wherein the wiring film has a Cap film made of a Cap film alloy and has a body film with lower resistivity than the Cap film, wherein when the number of atoms of the Cap film alloy is 100 at %, the Cap film alloy contains Cu of more than 50 at % and Ca of 0.5 at % or more, and wherein the Cap film contacts an insulating film containing Si oxide.

In the first, third, fifth, and seventh embodiments described above, it is possible to obtain Mg as the additive metal in a range of 0.5 at % or more and less than 7%.

Further, in the first, third, fifth, and seventh embodiments, it is possible to obtain Si as the additive metal in a range of 0.5 at % or more and less than 15%.

In the first, third, fifth, and seventh embodiments, it is possible to obtain Ni as the additive metal in a range of 3 at % or more and less than 50%.

A Si oxide thin film is formed on the Cap film by a CVD method so as to be in close or direct contact with the Cap film.

1. A Cu alloy target including a Cap film alloy, wherein, when the number of atoms of the Cap film alloy is 100 at %, the Cap film alloy comprises:
Cu: more than 50 at %
an additive metal comprising Si: 0.5 at % or more and less than 15 at %: and
Al: 0.5 at % or more.

2-5. (canceled)
